(19) United States
(12) Patent Application Publication
(10) Pub. No.: US 2018/0331170 A1
(43) Pub. Date: Nov. 15, 2018

(54) CONNECTION COMPONENT, CONNECTOR, MANUFACTURING METHOD FOR THE SAME AND PANEL COMPONENT

(71) Applicant: Wuhan China Star Optoelectronics Technology Co., Ltd., Wuhan, Hubei (CN)

(72) Inventor: Kui XU, Shenzhen, Guangdong (CN)

(73) Assignee: Wuhan China Star Optoelectronics Technology Co., L td., Wuhan, Hubei (CN)

(21) Appl. No.: 15/553,266

(22) PCT Filed: May 25, 2017
(86) PCT No.: PCT/CN2017/085841

§ 371 Date: Aug. 24, 2017

(30) Foreign Application Priority Data
May 10, 2017 (CN) 201710325515.2

(51) Int. Cl. H01L 27/32; H01L 23/00; H01L 23/498; H01L 25/18; H05K 1/18; H05K 1/14; H05K 1/11

(52) U.S. Cl. CPC H01L 27/3276; H05K 3/4007; H01L 24/16; H01L 24/29; H01L 24/11; H01L 23/4985; H01L 25/18; H01L 24/32; H01L 24/73; H05K 1/189; H05K 1/147; H05K 1/111; H01L 2224/13144; H01L 2224/13147; H01L 2224/13019; H01L 2224/16238; H01L 2224/2929; H01L 2224/29298; H01L 2224/29028; H01L 2224/11614; H01L 2924/2064; H01L 2224/16148; H01L 2224/13166; H01L 2224/13124; H01L 2224/1318; H01L 2224/32145; H01L 2224/32225; H01L 2224/73204; H05K 2201/10128; H05K 2201/10977; H05K 2201/1078; H05K 2201/10787; H01L 2224/1145; H01L 24/13

(57) ABSTRACT

The present invention discloses a connection component, connector, manufacturing method for the same and panel component. The connection component includes a first connector and a second connector electrically connected to the first connector, wherein, between the first connector and the second connector, a connection adhesive is provided, the first connector and/or the second connector both include a base body and multiple connection terminals, wherein the multiple connection terminals are disposed on the base body, a terminal portion of each connection terminal has a protrusion, the protrusion has a saw-tooth shape, and the saw-tooth shape has a regular pattern or a non-regular pattern, Accordingly, the present invention can enhance the reliability of the connection and increase the production yield.

### BACKGROUND OF THE INVENTION

### 1. Field of the Invention

The present invention relates to a connector technology and more particularly to a connection component, a connector, manufacturing method for the same and panel component.

### 2. Description of Related Art

Along with the development of the flat display technology, people demands for higher fine degree image of a display, and selecting for high PPI (Pixels per Inch) display has become a standard configuration of an electric product.

In a traditional method for manufacturing a high PPI display device, a manufacturing process is manufacturing a TFT (Thin Film Transistor) backplane→manufacturing a light-emitting layer (liquid crystal cell forming/OLED (Organic Light-Emitting Diode) vapor deposition)→bonding (connection for a module electric part and a display device)→product assembly. However, along with the improvement of the fine degree image of a display, the number of the terminals of the module electric part such as IC (Integrated Circuit), FPC (Flexible Printed Circuit) is increased correspondingly. More terminals are required to be manufactured on a same area so that an area of each terminal, a distance between terminals will be decreased correspondingly. When the distance between terminals is decreased to be less than a certain degree, a short circuit will happen. The short circuit will cause an abnormal and a functional poor of the product, or a scrap of the product.

### SUMMARY OF THE INVENTION

The technology problem mainly solved by the present invention is to provide a connection component, a connector and manufacturing method for the same in order to avoid a short circuit among the terminals, enhance the reliability of the connection and increase the production yield.

In order to solve the above technology problem, a technology solution adopted by the present invention is: a connection component, comprising: a first connector; and a second connector electrically connected to the first connector, wherein, between the first connector and the second connector, a connection adhesive is provided, the first connector and/or the second connector both include a base body and multiple connection terminals, wherein the multiple connection terminals are disposed on the base body, a terminal portion of each connection terminal has a protrusion, the protrusion has a saw-tooth shape, and the saw-tooth shape has a regular pattern or a non-regular pattern.

In order to solve the above technology problem, a technology solution adopted by the present invention is: a connector, comprising: a base body; multiple connection terminals disposed on the base body, a terminal portion of each connection terminal has a protrusion.

In order to solve the above technology problem, a technology solution adopted by the present invention is: a panel component comprising: a panel; a first connector; and a second connector electrically connected to the first connector, wherein, between the first connector and the second connector, a connection adhesive is provided, the first connector and/or the second connector both include a base body and multiple connection terminals, wherein the multiple connection terminals are disposed on the base body, a terminal portion of each connection terminal has a protrusion.

The beneficial effect of the present invention is: comparing with the conventional art, the present embodiment discloses a connection component. The connection component includes a first connector and a second connector. The second connector is electrically connected to the first connector. The terminal portion of the connection terminal of the first connector and/or the second connector both has a protrusion. The protrusion can be inserted into the terminal portion of another connection terminal in order to avoid a short circuit among the terminals, enhance the reliability of the connection and increase the production yield.

### BRIEF DESCRIPTION OF THE DRAWINGS

FIG. 1 is a schematic diagram of a connector according to a first embodiment of the present invention;

FIG. 2 is a schematic diagram of a protrusion of the terminal portion of the connection terminal of the connector of the present invention;

FIG. 3 is a schematic structure diagram of the connector according to a second embodiment of the present invention;

FIG. 4 is a schematic structure diagram of the connector according to a third embodiment of the present invention;

FIG. 5 is a schematic structure diagram of the connector according to a fourth embodiment of the present invention;

FIG. 6 is a schematic structure diagram of the connector according to a fifth embodiment of the present invention;

FIG. 7 is a schematic flow chart of a manufacturing method for a connector according to the present invention;

FIG. 8 is a schematic flow chart of a manufacturing method for a connector according to the present invention;

FIG. 9 is a schematic diagram of a connection component according to a first embodiment of the present invention;

FIG. 10 is a schematic diagram of a connection component according to a second embodiment of the present invention;

FIG. 11 is a schematic diagram of a connection component according to a third embodiment of the present invention;

FIG. 12 is a schematic diagram of a connection component according to a fourth embodiment of the present invention;

FIG. 13 is a schematic diagram of a connection component according to a fifth embodiment of the present invention;

FIG. 14 is a schematic diagram of a panel component according to a first embodiment of the present invention; and

FIG. 15 is a schematic diagram of a panel component of another embodiment of the present invention.

### DETAILED DESCRIPTION OF THE PREFERRED EMBODIMENT

The following will combine the figures and embodiments for describe the present invention in detail.

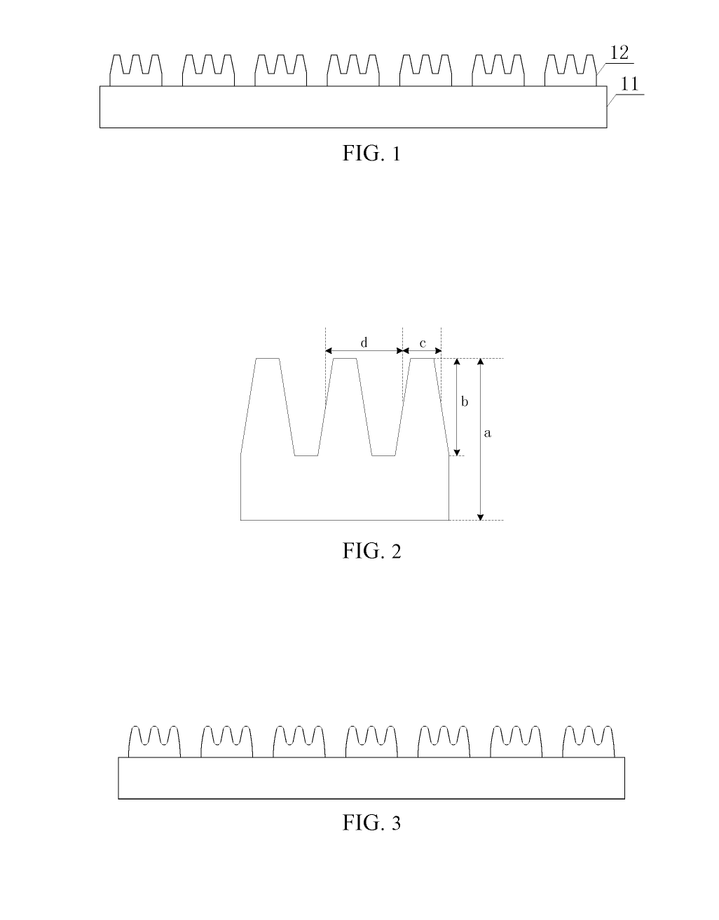

With reference to FIG. 1, and FIG. 1 is a schematic diagram of a connector according to a first embodiment of the present invention. As shown in FIG. 1, the connector 10 of the present embodiment includes: a base body 11 and multiple connection terminals 12 disposed on the base body 11, and a terminal portion of each connection terminal 12 has a protrusion.

Wherein, the base body 11 can be a TFT (Thin Film Transistor) backplane, an IC (Integrated Circuit) or a FPC (Flexible Printed Circuit).

Wherein, the protrusion of the terminal portion of each connection terminal 12 has a saw-tooth shape. Specifically, the saw-tooth shape has a regular pattern, or a non-regular pattern. Furthermore, the saw-tooth shape is trapezoidal, wavy, triangular or rectangular. Furthermore, an arrangement order of the connection terminals 12 is decided according to an actual situation.

In one embodiment, as shown in FIG. 2, FIG. 2 is a schematic diagram of a protrusion of the terminal portion of the connection terminal of the connector of the present invention. In FIG. 2, a range of a height “a” of the protrusion is 1.2 microns≤a≤3.5 microns. A range of a height of a saw-tooth of the protrusion “b” is 1 microns≤b≤3 microns. A range of a width of the protrusion “c” is 3 microns≤c≤5 microns. A range of a pitch “d” among the saw-teeth is 3 microns≤c≤5 microns.

Specifically, when the saw-tooth shape is wavy, as shown in FIG. 3, FIG. 3 is a schematic structure diagram of the connector according to a second embodiment of the present invention. In FIG. 3, the saw-tooth shape of each protrusion of the terminal portion of the connection terminal of the connector is wavy.

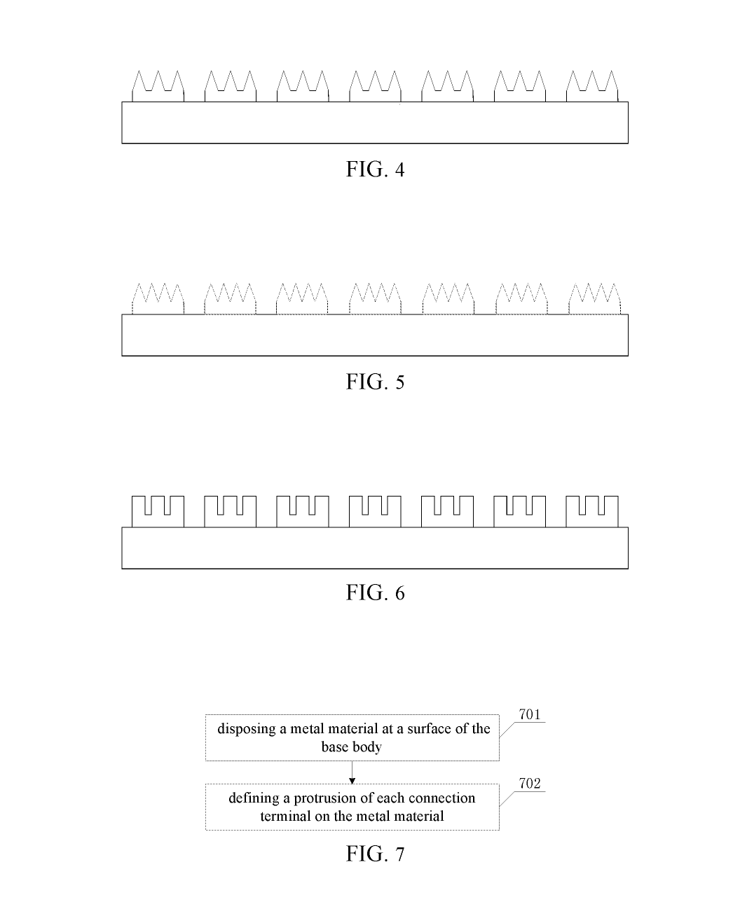

Specifically, when the saw-tooth shape is triangular, as shown in FIG. 4, FIG. 4 is a schematic structure diagram of the connector according to a third embodiment of the present invention. In FIG. 4, a top portion of each protrusion of the terminal portion of the connection terminal of the connector is sharp and a bottom portion is flat.

Specifically, when the saw-tooth shape is triangular, as shown in FIG. 5, FIG. 5 is a schematic structure diagram of the connector according to a fourth embodiment of the present invention. In FIG. 5, a top portion and a bottom portion of each protrusion of the terminal portion of the connection terminal of the connector are both sharp.

Specifically, when the saw-tooth shape is rectangular, as shown in FIG. 6, FIG. 6 is a schematic structure diagram of the connector according to a fifth embodiment of the present invention. In FIG. 6, the saw-tooth shape of each protrusion of the terminal portion of the connection terminal of the connector is rectangular.

In the present embodiment, the connector includes: a base body, multiple connection terminals disposed on the base body, and a terminal portion of each connection terminal has a protrusion. Each protrusion can embed into a terminal portion of another connection terminal in order to avoid a short circuit phenomenon, increasing reliability.

With reference to FIG. 7, and FIG. 7 is a schematic flow chart of a manufacturing method for a connector according to the present invention. It should be noted that if the result is substantially the same, the method of the present invention is not limited to the sequence shown in FIG. 7. As shown in FIG. 7, the method includes following steps:

S701: disposing a metal material at a surface of the base body.

Specifically, before the step of disposing a metal material at a surface of the base body, cleaning the surface of the base body.

Specifically, the present embodiment can dispose the metal material on the surface of the base body by a coating method, or other methods.

S702: defining a protrusion of each connection terminal on the metal material.

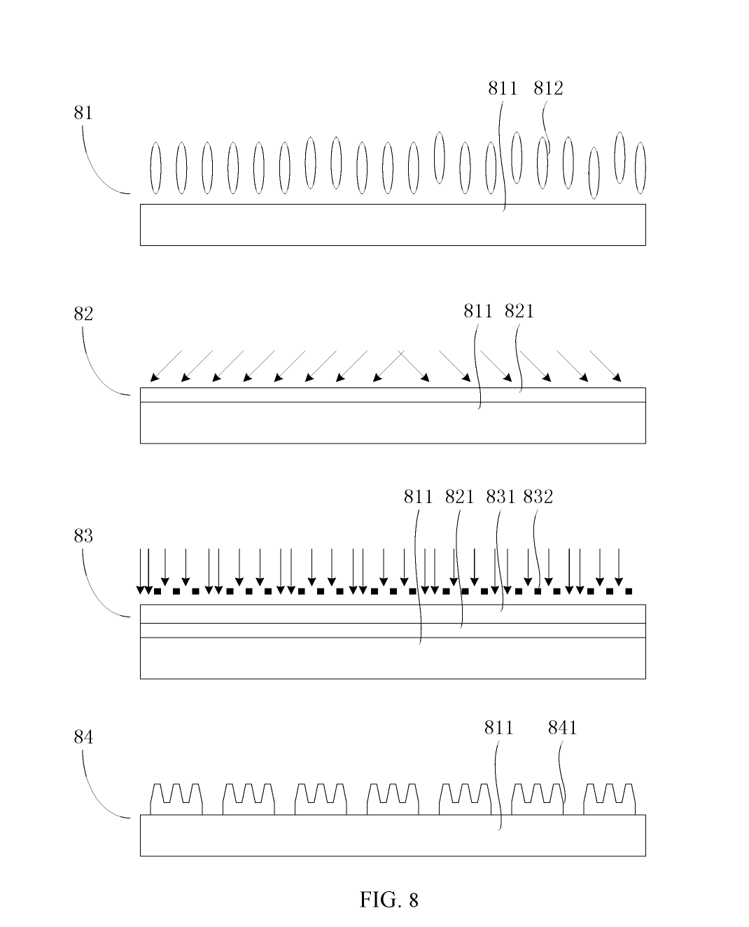

With reference to FIG. 8, an embodiment of a manufacturing method for a connector of the present invention includes:

Step S81: cleaning the substrate;

Using a cleaning fluid 812 to clean a base body 811, wherein, the cleaning fluid 812 can be pure water.

Step S82: disposing the metal material on the substrate;

Using a sputtering process to dispose the metal material 821 on the surface of the base body 811. Specifically, the sputtering process means that in a vacuum environment, inputting certain of an inert gas into a chamber. Then, accelerating the inert gas to impact a target such that atoms on the target surface is hit to be out, and form an even coating film of the surface of the base body. Wherein, the inert gas can be argon, the target can be a metal material. It should be noted that a thickness of the coating film is equal to a height of the protrusion of the terminal portion of the connection terminal of the connector.

Step S83: exposing the base body;

After disposing the metal material 821 on the surface of the base body 811, disposing a photoresist 831 on the metal material layer 821. Then, disposing a mask 832 on the photoresist 831. Then, exposing the photoresist 831. It should be noted that a hollow shape of the mask 832 is preset, and matched with the shape of the protrusion of the terminal portion of the connection terminal of the connector.

Step S84: etching the base body after being exposed and stripping the photoresist;

Performing a wet etching to the photoresist 831 after being exposed and the metal material layer 821 in order to etch a saw-tooth shape of the protrusion of the connection terminal of the connection terminal of the connector. Then, stripping the photoresist 831 in order to obtain a connection terminal 841 of the connector.

In the present embodiment, disposing the metal material on the surface of the base body. Then, defining the protrusion of each connection terminal such that the protrusion of the terminal portion of the connector is manufactured through a conventional art, no additional cost will be increased.

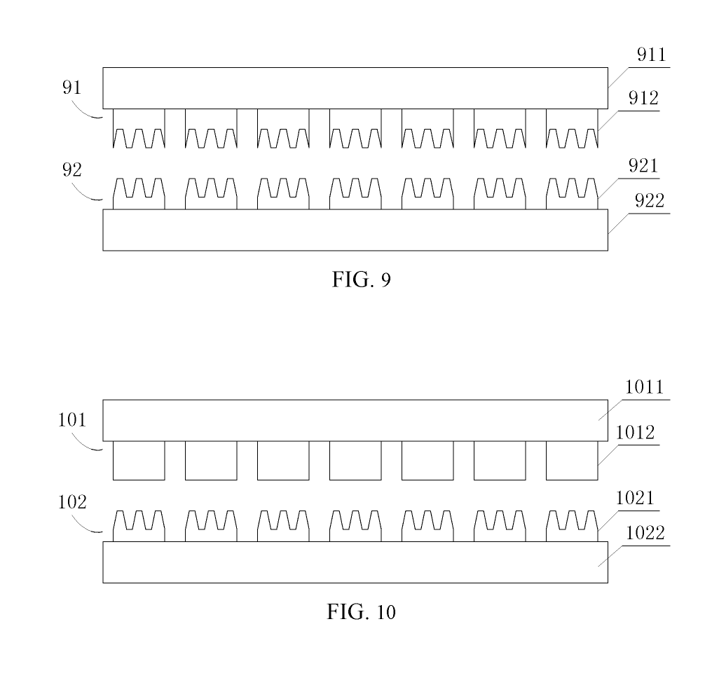

With reference to FIG. 9, and FIG. 9 is a schematic diagram of a connection component according to a first embodiment of the present invention. Wherein, the connection component 90 includes a first connector and a second connector 92. The first connector 91 and the second connector 92 are electrically connected. The first connector 91 and the second connector 92 are both the connectors in the above embodiments.

Specifically, the first connector 91 includes a first base body 911 and a first connection terminal 912. Wherein, the first connection terminal 912 is disposed on the first base body 911, and a terminal portion of the first connection terminal 912 has a protrusion. The second connector 92 includes a second base body 922 and a second connection terminal 921. Wherein, the second connection terminal 921 is disposed on the second base body 922, and a terminal portion of the second connection terminal 921 has a protrusion.

Optionally, a shape of the protrusion of the connection terminal 912 of the first connector 91 and a shape of the connection terminal 921 of the second connector 92 are complementary. The protrusion of the connection terminal 912 of the first connector 91 can be inserted into the protrusion of the connection terminal 921 of the second connector 92.

Optionally, as shown in FIG. 10, FIG. 10 is a schematic diagram of a connection component according to a second embodiment of the present invention. In FIG. 10, the connection terminal 1012 of the first connector 101 is rectangular. A width of the connection terminal 1012 is generally larger than the width of the connection terminal 1021 of the second connector 102. The protrusion of the connection terminal 1021 of the second connector 102 can be inserted into the connection terminal 1012 of the first connector 101. It should be noted that a hardness of a material of the connection terminal 1021 of the first connector 101 is less than a hardness of a material of the connection terminal 1021 of the second connector 102. Specifically, a material of the connection terminal 1012 of the first connector 101 is gold or copper. A material of the connection terminal 1021 of the second connector 102 is titanium-aluminum-titanium or molybdenum-aluminum-molybdenum.

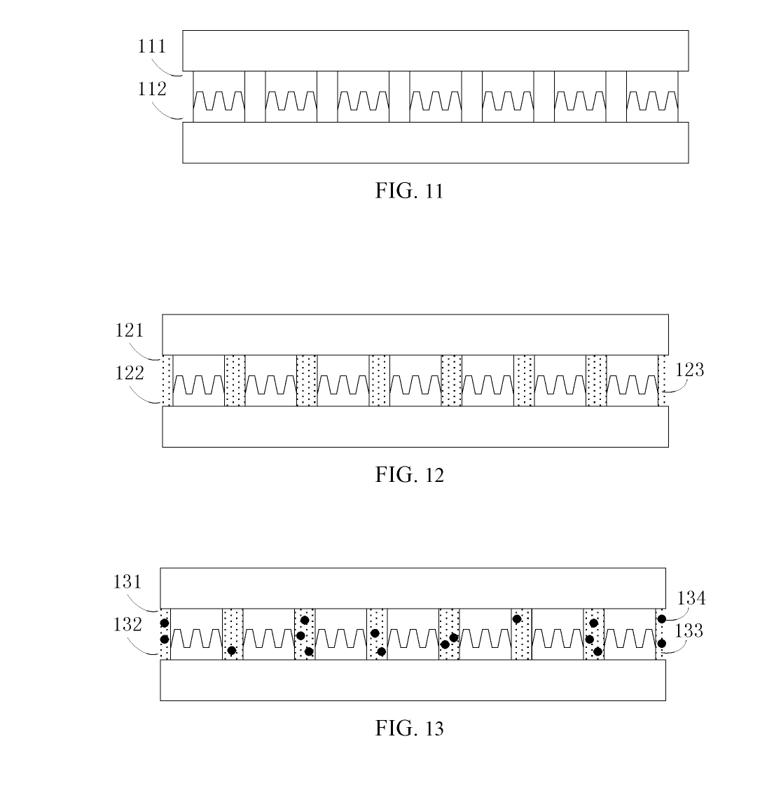

As shown in FIG. 11, FIG. 11 is a schematic diagram of a connection component according to a third embodiment of the present invention. FIG. 11 is a schematic diagram after the protrusion of the connection terminal of the second connector in FIG. 9 and FIG. 10 is inserted into the connection terminal of the first connector.

Furthermore, as shown in FIG. 12, FIG. 12 is a schematic diagram of a connection component according to a fourth embodiment of the present invention. Wherein, the connection component 120 includes a first connector 121, a second connector 122 and a connection adhesive 123. Wherein, the connection adhesive 123 is an insulated adhesive. The connection adhesive 123 can also be a hot press adhesive without having conductive particles. Specifically, the connection adhesive 123 is Polyimide (PI), Acrylic. The connection adhesive 123 can realize a physical connection between the first connector 121 and the second connector 122. For the hot press adhesive, because the conductive particles are not existed, a short circuit among the conductive particles among the adjacent terminals can be avoided.

Furthermore, as shown in FIG. 13, FIG. 13 is a schematic diagram of a connection component according to a fifth embodiment of the present invention. Wherein, the connection component 130 includes a first connector 131, a second connector 132, a connection adhesive 133 and conductive particles 134. A density of the conductive particles 134 is less than a density threshold. Wherein, the density threshold is a critical value that cause a short circuit between adjacent connection terminals. Specifically, the connection adhesive 133 is an ACF (Anisotropic Conductive Film).

In the present embodiment, the connection component includes a first connector and a second connector. The second connector is electrically connected to the first connector. The terminal portion of the connection terminal of the first connector and/or the second connector both has a protrusion. The protrusion can be inserted into the terminal portion of another connection terminal in order to avoid a short circuit among the terminals, enhance the reliability of the connection and increase the production yield.

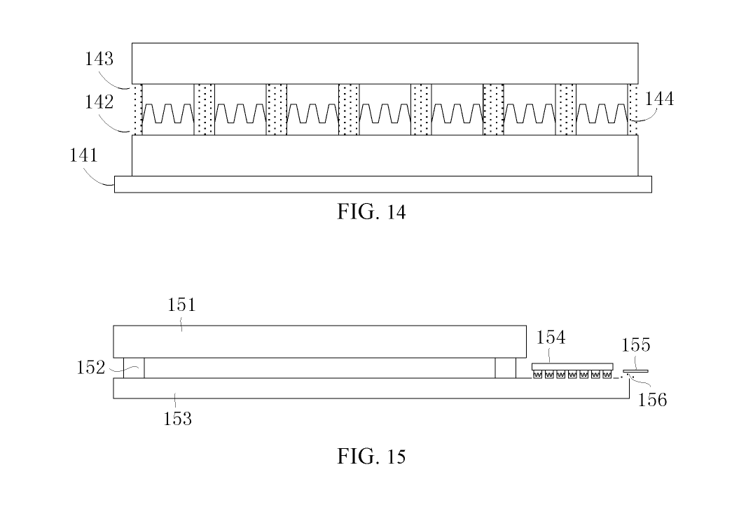

With reference to FIG. 14, and FIG. 14 is a schematic diagram of a panel component according to a first embodiment of the present invention. Wherein, the panel component 140 includes a panel 141, a first connector142 and a second connector 143. Wherein, the first connector 142 is disposed at a side of the panel 141, the first connector 142 and the second connector 143 are electrically connected. The first connector 142 and the second connector 143 are both the connectors in the above embodiments.

Wherein, a hardness of a material of the connection terminal of the first connector 142 is greater than a hardness of a material of the connection terminal of the second connector 143. Specifically, a material of the connection terminal of the first connector 142 is titanium-aluminum-titanium or molybdenum-aluminum-molybdenum. A material of the connection terminal of the second connector 143 is gold or copper.

Furthermore, between the first connector 142 and the second connector 143, a connection adhesive 144 is filled. Specifically, the connection adhesive 144 can be polyimide, acrylic or ACF.

In the present embodiment, the panel component includes a first connector and a second connector. The first connector and the second connector are disposed on the panel. The second connector is electrically connected to the first connector. The terminal portion of the connection terminal of the first connector and/or the second connector both has a protrusion. The protrusion can be inserted into the terminal portion of another connection terminal in order to avoid a short circuit among the terminals, enhance the reliability of the connection and increase the production yield.

With reference to FIG. 15, FIG. 15 is a schematic diagram of a panel component of another embodiment of the present invention. Wherein, the panel component 150 includes a package cover 151, a sealing glue 151, a TFT backplane/OLED panel 153, a module electric component 154, FPC 155 and connecting material 156.

Wherein, a terminal portion of a connector of each of the TFT backplane/OLED panel 153 and the module electric component 154 has more than three protrusions. The protrusions can be inserted into terminal portions of the connection terminals with each other.

Wherein, the module electric component 154 is an IC, 155 is an FPC.

Wherein, FPC 155 is fixed to a terminal of the TFT backplane 153 through connecting material 156.

Optionally, the connecting material can be the connector mentioned above, or traditional connecting material ACF(Anisotropic Conducting Film).

Furthermore, a material of the connection terminal of the connector of the TFT backplane 153 is titanium-aluminum-titanium, and a material of the connection terminal of the connector of the module electric component 154 is gold.

In the present embodiment, the panel component includes a first connector and a second connector. The first connector and the second connector are disposed on the panel. The second connector is electrically connected to the first connector. The terminal portion of the connection terminal of the first connector and/or the second connector both has a protrusion. The protrusion can be inserted into the terminal portion of another connection terminal in order to avoid a short circuit among the terminals, enhance the reliability of the connection and increase the production yield.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A connection component, comprising:
a first connector; and
a second connector electrically connected to the first connector, wherein, between the first connector and the second connector, a connection adhesive is provided, the first connector and/or the second connector both include a base body and multiple connection terminals, wherein the multiple connection terminals are disposed on the base body, a terminal portion of each connection terminal has a protrusion, the protrusion has a saw-tooth shape, and the saw-tooth shape has a regular pattern or a non-regular pattern.

2. The connection component according to claim 1, wherein,
a height of the protrusion of the connector is 1.2-3.5 microns;
a height of the saw-tooth shape of the protrusion of the connector is 1-3 microns, which is less than the height of the protrusion of the connector, a width of the protrusion is 3-5 microns, and the saw-tooth shape includes multiple saw-teeth, and a pitch among the saw-teeth is 3-5 microns.

3. The connection component according to claim 1, wherein,
the saw-tooth shape is trapezoidal, wavy, triangular or rectangular.

4. The connection component according to claim 1, wherein,
the protrusion of the connection terminal of the first connector is inserted into the connection terminal of the second connector.

5. The connection component according to claim 1, wherein,
the connection adhesive has or does not has conductive particles, if the connection adhesive has the conductive particles, a density of the conductive particles is less than a density threshold, and the density threshold is a critical value that cause a short circuit between adjacent connection terminals.

6. The connection component according to claim 5, wherein,
the connection adhesive having the conductive particles is an anisotropic conductive film, and the connection adhesive without having the conductive particles is a hot-press adhesive.

7. A connector, comprising:
a base body;
multiple connection terminals disposed on the base body, a terminal portion of each connection terminal has a protrusion.

8. The connector according to claim 7, wherein,
the protrusion of the connector includes multiple saw-teeth and has a saw-tooth shape, and the saw-tooth shape has a regular pattern or a non-regular pattern.

9. The connector according to claim 7, wherein,
a height of the protrusion of the connector is 1.2-3.5 microns;
a height of the saw-tooth shape of the protrusion of the connector is 1-3 microns, which is less than the height of the protrusion of the connector, a width of the protrusion is 3-5 microns, and the saw-tooth shape includes multiple saw-teeth, and a pitch among the saw-teeth is 3-5 microns.

10. The connector according to claim 8, wherein,
the saw-tooth shape is trapezoidal, wavy, triangular or rectangular.

11. A panel component comprising:
a panel;
a first connector; and
a second connector electrically connected to the first connector, wherein, between the first connector and the second connector, a connection adhesive is provided, the first connector and/or the second connector both include a base body and multiple connection terminals, wherein the multiple connection terminals are disposed on the base body, a terminal portion of each connection terminal has a protrusion.

12. The panel component according to claim 11, wherein,
the protrusion of the first connector and/or the second connector has a saw-tooth shape, and the saw-tooth shape has a regular pattern or a non-regular pattern.

13. The panel component according to claim 11, wherein,
a height of the protrusion of the connector is 1.2-3.5 microns;
a height of the saw-tooth shape of the protrusion of the connector is 1-3 microns, which is less than the height of the protrusion of the connector, a width of the protrusion is 3-5 microns, and the saw-tooth shape includes multiple saw-teeth, and a pitch among the saw-teeth is 3-5 microns.

14. The panel component according to claim 12, wherein,
the saw-tooth shape is trapezoidal, wavy, triangular or rectangular.

15. The panel component according to claim 11, wherein,
a hardness of a material of the connection terminal of the first connector is greater than a hardness of a material of the connection terminal of the second connector.

16. The panel component according to claim 11, wherein,
the panel is a display panel, the first connector is a connection side of the display panel, and the second connector is a connection side of a driving IC of the display panel and/or a connection side of a flexible circuit board.

17. The panel component according to claim 15, wherein,
a material of the connection terminal of the first connector is titanium-aluminum-titanium or molybdenum-aluminum-molybdenum.

18. The panel component according to claim 15, wherein,
a material of the connection terminal of the second connector is gold or copper.
